(19) United States
(12) Patent Application Publication
(10) Pub. No.: US 2025/0079361 A1
(43) Pub. Date: Mar. 6, 2025

(54) EXTERNAL CONNECTION PAD APPARATUS AND SEMICONDUCTOR APPARATUS INCLUDING THE SAME

(71) Applicant: SK hynix Inc., Icheon-si Gyeonggi-do (KR)

(72) Inventors: Yang Ho SUR, Icheon-si Gyeonggi-do (KR); Sun Ki CHO, Icheon-si Gyeonggi-do (KR)

(73) Assignee: SK hynix Inc., Icheon-si Gyeonggi-do (KR)

(21) Appl. No.: 18/428,240

(22) Filed: Jan. 31, 2024

(30) Foreign Application Priority Data
Aug. 29, 2023 (KR) 10-2023-0113659

(51) Int. Cl. H01L 23/00

(52) U.S. Cl. CPC H01L 24/06; H01L 24/05; H01L 24/20; H01L 2224/05554; H01L 2224/0603; H01L 2224/06051; H01L 2224/214; H01L 2924/30105

(57) ABSTRACT

An external connection pad apparatus includes a first pad and a second pad. The first pad has a first surface area. The second pad has a second surface area larger than the first surface area.

### CROSS-REFERENCES TO RELATED APPLICATION

The present application claims priority under 35 U.S.C. § 119 (a) to Korean application number 10-2023-0113659 filed on Aug. 29, 2023, in the Korean Intellectual Property Office, which is incorporated herein by reference in its entirety.

### BACKGROUND

### 1. Technical Field

Various embodiments generally relate to an electronic device, and, more particularly, to external connection pad and semiconductor apparatus including the same.

### 2. Related Art

A semiconductor apparatus may include an integrated circuit having various functions. Pads may be formed on a designated area of the semiconductor apparatus to connect the semiconductor apparatus with an external terminal.

The semiconductor apparatus is electrically connected to an external device through the pads, and can receive power signals, control signals, and the like, and can transmit and receive data through the pads.

As the need to process large amounts of data at high speeds increases, research continues to improve the operating speed of semiconductor apparatus.

### SUMMARY

In an embodiment, an external connection pad apparatus may include a first pad and a second pad. The first pad may have a first surface area. The second pad may have a second surface area larger than the first surface area.

In an embodiment, a semiconductor apparatus may include an integrated circuit, an interconnection layer, and an external connection pad apparatus. The interconnection layer may be electrically connected to the integrated circuit. The external connection pad apparatus may include a plurality of first pads, each first pad having a first surface area, and a plurality of second pads, each second pad having a second surface area larger than the first surface area, wherein each of the plurality of first pads and each of the plurality of second pads are electrically connected with the interconnection layer.

In an embodiment, an external connection pad apparatus may include a plurality of first pads and a plurality of second pads. Each first pad may have a first surface area, may comprise a first connection unit including a first connection surface to which a first connection member connects, and may comprise a second connection unit extending outwardly from the first connection unit, wherein the second connection unit may include at least one contact connecting the first pad to a first interconnection layer. Each second pad may having a second surface area larger than the first surface area, may comprise a third connection unit including a second connection surface to which a second connection member connects, and may comprise a fourth connection unit extending outwardly from the third connection unit, wherein the fourth connection unit may include at least one contact connecting the second pad to a second interconnection layer.

### BRIEF DESCRIPTION OF THE DRAWINGS

FIG. 1 is a diagram of a semiconductor apparatus according to an embodiment of the present disclosure.

FIG. 2 is a diagram of a semiconductor apparatus according to an embodiment of the present disclosure.

FIG. 3 is a diagram of a first pad according to an embodiment of the present disclosure.

FIG. 4 is a diagram of a second pad according to an embodiment of the present disclosure.

FIG. 5 is a graph illustrating a relationship between pad area and input/output capacitance according to an embodiment of the present disclosure.

### DETAILED DESCRIPTION

Various embodiments may provide external connection pad capable of supporting high-speed operation and a semiconductor apparatus including the same.

Various embodiments may improve noise characteristics and high-speed data transmission and reception capability by reducing the cross-talk caused by the external connection pad.

Various embodiments may reduce the cost of manufacturing semiconductor apparatus by minimizing the area of the pads.

Various embodiments of the present disclosure will be described in detail with reference to the accompanying drawings.

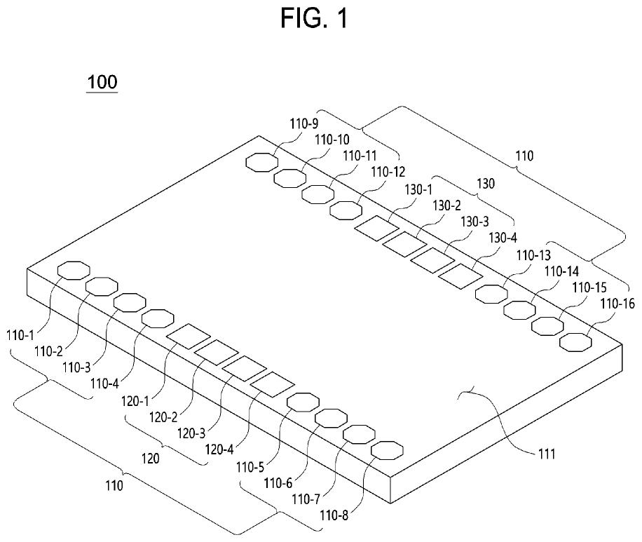

FIG. 1 is a diagram of a semiconductor apparatus according to an embodiment of the present disclosure.

Referring to FIG. 1, a semiconductor apparatus 100 according to an embodiment may be provided with a plurality of external connection pads 110-1, 110-2, 110-3, 110-4, 110-5, 110-6, 110-7, 110-8, 110-9, 110-10, 110-11, 110-12, 110-13, 110-14, 110-15, 110-16, (collectively “110-1 to 110-16”) 120-1, 120-2, 120-3, 120-4, (collectively “120-1 to 120-4”) 130-1, 130-2, 130-3, and 130-4 (collectively “130-1 to 130-4”) on a first surface 111. The plurality of external connection pads 110-1 to 110-16, 120-1 to 120-4, 130-1 to 130-4 may be referred to as bonding pads but are not particularly limited to such a reference.

The external connection pads 110-1 to 110-16, 120-1 to 120-4, 130-1 to 130-4 may include a first pad group 110 including a plurality of first pads 110-1 to 110-16, a second pad group 120 including a plurality of second pads 120-1 to 120-4, and a third pad group 130 including a plurality of third pads 130-1 to 130-4.

In an embodiment, data may be transmitted and received via the first pad group 110 to and from an external device, such as a package substrate (not shown). The second group of pads 120 may receive power signals (power voltage, ground voltage) from a power supply (not shown). The third pad group 130 may receive control signals (clock signal, chip enable signal, and so forth) from an external device.

A surface area of each of the first pads 110-1 to 110-16 in the first pad group 110 may be formed smaller than a surface area of each of the second pads 120-1 to 120-4 in the second pad group 120 and smaller than a surface area of each of the third pads 130-1 to 130-4 in the third pad group 130.

For example, each of the second pads 120-1 to 120-4 and each of the third pads 130-1 to 130-4 may be configured as an overall square. Each of the first pads 110-1 to 110-16 may be configured having a shape similar to the second pads 120-1 to 120-4 and the third pads 130-1 to 130-4 but with at least one edge chamfered in plan view, such as a polygon having five or more angles.

Minimizing the parasitic components of pads involved with data transmitting and receiving, for example, the first pad group 110, results in improved data transmission rate of the semiconductor apparatus 100.

As shown in FIG. 1, by forming each pad of the first pad group 110 for data transmission and reception with a smaller size, such as surface area, than the size, such as surface area of each pad of the second pad groups 120 and each pad of the third pad groups 130, the input/output capacitance Cio of the first pad group 110 is reduced, enabling data transmission/reception at a higher speed than with pads the size of the second pad groups 120 and the third pad groups 130.

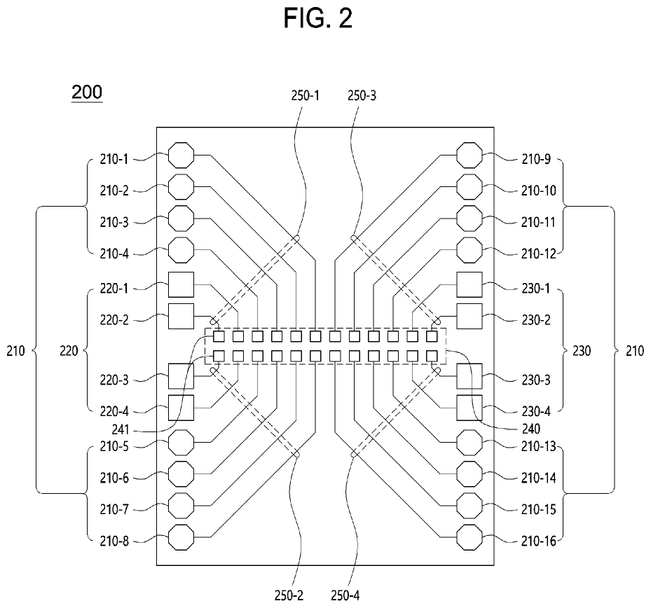

FIG. 2 is a diagram of a semiconductor apparatus according to an embodiment of the present disclosure.

Referring to FIG. 2, the semiconductor apparatus 200 according to an embodiment may include a chip pad group 240 including a plurality of chip pads 241. Each chip pad 241 of the chip pad group 240 may be connected via wiring (not shown) to an integrated circuit (not shown) formed beneath the surface of the semiconductor apparatus 200.

Each of the chip pads 241 of the chip pad group 240 is electrically connected to a different one of the external connection pads 210, 220, 230 via an interconnection layer, for example, a wiring layer, a conductive layer, metal layer, or re-distribution layer (RDL). In an embodiment, the interconnection layer may be a re-distribution layer that connects the plurality of chip pads 241 with the plurality of external connection pads 210, 220, 230.

The interconnection layers 250-1, 250-3, 250-3, and 250-4 (collectively “250-1 to 250-4”) are electrically connected individually to a different one of each of the chip pads 241 of the chip pad group 240 and may include a conductive pattern that extends from a region where the chip pads 241 are located to other regions. The interconnection layers 250-1 to 250-4 may extend the chip pads 241 to connection points with electrical connection members, such as wire bonds or bumps. By means of the interconnection layers 250-1 to 250-4, the points where the connection members are connected to the semiconductor apparatus 200 may be changed or extended to other areas spaced apart from the chip pad 241 locations.

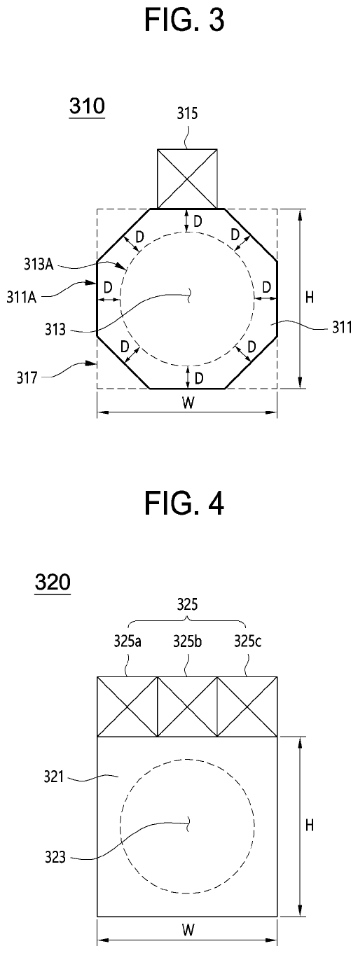

FIG. 3 is a diagram of a first pad according to an embodiment of the present disclosure.

FIG. 3 is a top view of a first pad 310 that may be used as a pad through which data is transmitted/received pad.

The first pad 310 may include any of the first pads of FIG. 1 and FIG. 2, for example, each of the first pads 110-1 to 110-16 comprising the first pad group 110 of FIG. 1 or each of the first pads 210-1, 210-2, 210-3, 210-4, 210-5, 210-6, 210-7, 210-8, 210-9, 210-10, 210-11, 210-12, 210-13, 210-14, 210-15, and 210-16 (collectively “210-1 to 210-16”) comprising the first pad group 210 of FIG. 2.

Referring to FIG. 3, the first pad 310 may include a first connection unit 311 and a second connection unit 315.

A designated area within the first connection unit 311 may form a connection surface 313 on which a connection member, such as a wire bond or bump, may be formed. The second connection unit 315 extends outwardly from an outer edge 311A or perimeter of the first connection unit 311 and connects the first pad 310 with an integrated circuit formed within the semiconductor apparatus 100, 200. For example, the second connection unit 315 electrically connects the interconnection layers 250-1 to 250-4 of FIG. 2 to the first pad 310. In an embodiment, the second connection unit 315 may comprise a contact.

In one embodiment, the distance D from the outer edge 311A of the first connection unit 311 to an outer edge 313A or perimeter of the connection surface 313 may be the same at various different points around the outer edge 313A of the connection surface 313. For example, the outer edge 311A of the first connection unit 311 may be equidistant at distance D with the outer edge 313A of the connection surface 313 at various/numerous points around the outer edge 311A of the first connection unit 311, such as shown in FIG. 3.

The contact surface area where the connection member connects to or forms a joint with the connection surface 313 may be overall circular. For example, a connection member connects to the first pad 310 on the connection surface 313. Accordingly, the first connection unit 311, which is formed to be equidistantly spaced at various/numerous perimeter points with the outer edge 313A of the connection surface 313, may be configured in a circular or polygon shape with five or more angles, such as a pentagon, hexagon, heptagon, octagon, and so forth. When the shape of the outer edge 313A of the connection surface 313 matches the shape of the outer edge 311A of the first connection unit 311, and the outer edge 313A is centered with respect to the outer edge 311A, the distance from the outer edge 311A of the first connection unit 311 to an outer edge 313A of the connection surface 313 is formed equally or equidistantly.

For example, the first pad 310 is shaped with at least one corner of the pad area 317 chamfered, which is a rectangular shape with size W*H (W and H are each a real number). Thus, a surface area of the first pad 310, and ultimately a surface area of the first connection unit 311, is smaller than a surface area (W*H) of the pad area 317, thereby reducing the input/output capacitance Cio to allow data to be transferred and received at high speeds via the first pad 310.

FIG. 4 is a diagram of a second pad according to an embodiment of the present disclosure.

FIG. 4 is a top view of a second pad 320 that may be used or configured as a pad that receives at least one of a power signal or a control signal.

The second pad 320 may include any of the second pads of FIG. 1 and FIG. 2, for example, each of the second pads 120-1 to 120-4 comprising the second pad group 120 and each of the third pads 130-1 to 130-4 comprising the third pad group 130 of FIG. 1 or each of the second pads 220-1, 220-2, 220-3, and 220-4 (collectively “220-1 to 220-4”) comprising the second pad group 220 and each of the third pads 230-1, 230-2, 230-3, and 230-4 (collectively 230-1 to 230-4) comprising the third pad group 230 of FIG. 2.

Referring to FIG. 4, the second pad 320 may include a first connection unit 321 and a second connection unit 325.

In an embodiment, the first connection unit 321 is a rectangular shape with a W*H size. A designated area within the first connection unit 321 may constitute a connection surface 323 on which a connection member, such as a wire bond or bump, may be formed.

The second connection unit 325 extends outwardly from an outer edge or perimeter of the first connection unit 321 and connects the second pad 320 with an integrated circuit formed within the semiconductor apparatus 100, 200. For example, the second connection unit 325 electrically connects the interconnection layers 250-1 to 250-4 of FIG. 2 to the second pad 320. In an embodiment, the second connection unit 325 may include a plurality of contacts 325a, 325b, 325c.

Referring to FIG. 3 and FIG. 4, the second pad 320 may be formed in a W*H-sized rectangular shape and the first pad 310 may be formed in a pentagonal or other polygonal shape by chamfering at least one corner of the W*H-sized pad area 317.

Accordingly, the surface area of the first pad 310 is smaller than a surface area of the second pad 320. An area of the first connection unit 11, excluding the connection surface 313 of the first pad 310, is smaller than an area of the first connection unit 321, excluding the connection surface 323 of the second pad 320.

As a result, the first pad 310 has minimal input/output capacitance, which improves the speed of data transmission and reception through the first pad 310.

Referring to FIG. 3 and FIG. 4, the second connection unit 315 of the first pad 310 may comprise one contact, and the second connection unit 325 of the second pad 320 may comprise a plurality of contacts 325a, 325b, 325c.

Signals may be transmitted at a higher speed through the first pad 310 than through the second pad 320 because the surface area of the first pad 310 is smaller than the surface area of the second pad 320.

The second pad 320 may optionally have a reduced resistance component through the plurality of contacts 325a, 325b, 325c, which may minimize power loss through the second pad 320.

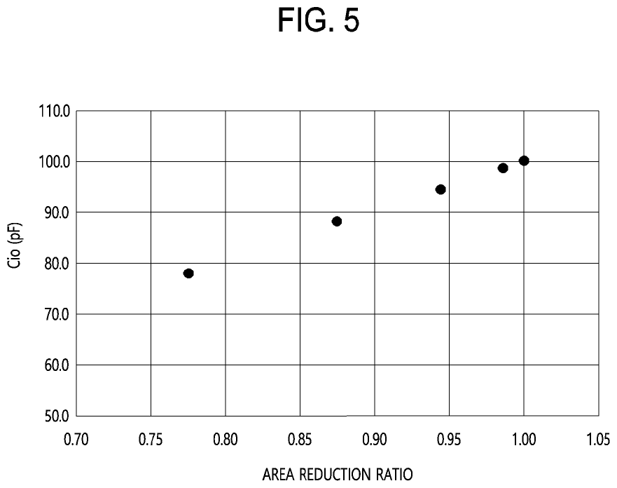

FIG. 5 is a graph illustrating a relationship between pad area and input/output capacitance according to an embodiment of the present disclosure.

Referring to FIG. 5, as the area of the first pad 310 decreases, the input/output capacitance Cio also decreases.

For example, if the area of the first pad 310 is not reduced, that is, when an area reduction ratio is 1.00, the input/output capacitance Cio is 100 pF. When the area reduction ratio is reduced to 0.78, the input/output capacitance Cio is reduced to 77.6 pF (far left point on the graph of FIG. 5), which can reduce the crosstalk caused by the connection pad.

Consider an example where the first pad 310 is configured in an octagonal shape by chamfering each corner of a square pad area 317 having a W*H size.

The input/output capacitance Cio of the pad before chamfering any of the corners is measured to be 69.7 pF, but the input/output capacitance Cio is measured to be 59.3 pF when the area reduction at the corners is 20 μm.

In other words, when the first pad 310 is configured in this embodiment, the input/output capacitance Cio can be reduced by about 15%, and the signal transmission speed can be improved accordingly.

A person skilled in the art to which the present disclosure pertains can understand that the present disclosure may be carried out in other specific forms without changing its technical spirit or essential features. Therefore, the embodiments described above are illustrative in all aspects, not limited. The scope of the present disclosure is defined by the claims to be described below rather than the detailed description, and the meaning and scope of the claims and all changes or modified forms derived from the equivalent concepts thereof are included in the scope of the present disclosure.

What is claimed is:

1. An external connection pad apparatus comprising:
a first pad having a first surface area; and
a second pad having a second surface area larger than the first surface area.

2. The external connection pad apparatus of claim 1, wherein the first pad comprises a pad through which data is at least one of transmitted and received.

3. The external connection pad apparatus of claim 1, wherein the first pad comprises a first connection unit including a connection surface to which a connection member connects; and
wherein a distance from an outer edge of the first connection unit to an outer edge of the connection surface is formed equally at various perimeter points of the outer edge of the first connection unit.

4. The external connection pad apparatus of claim 3, wherein the first pad includes a second connection unit extending outwardly from a part of the outer edge of the first connection unit, and
wherein the second connection unit includes a first quantity of contacts connecting the first pad to an interconnection layer.

5. The external connection pad apparatus of claim 1, wherein the first pad comprises a polygonal shape having five or more angles.

6. The external connection pad apparatus of claim 1, wherein the first pad has a shape comprising at least one chamfered edge from a rectangular pad area having a predetermined size.

7. The external connection pad apparatus of claim 1, wherein the second pad is a pad configured to receive at least one of a power signal and a control signal.

8. The external connection pad apparatus of claim 1, wherein the second pad includes a first connection unit, the first connection unit comprising a connection surface to which a connection member connects; and
wherein the first connection unit comprises a rectangular shape having a predetermined size.

9. The external connection pad apparatus of claim 8, wherein the second pad includes a second connection unit extending outwardly from a part of an outer edge of the first connection unit, and
wherein the second connection unit connects the second pad to an interconnection layer and includes a second quantity of contacts, wherein the quantity is two or more.

10. The external connection pad apparatus of claim 1, wherein the first pad has a shape comprising at least one chamfered edge from a rectangular pad area having a predetermined size, and
wherein the second pad comprises a rectangular shape having the predetermined size.

11. The external connection pad apparatus of claim 1:
wherein the first pad comprises:
a first connection unit comprising a first connection surface to which a first connection member connects; and
a second connection unit extending outwardly from a part of an outer edge of the first connection unit and including a first quantity of contacts connecting the first pad to a first interconnection layer; and
wherein the second pad comprises:
a third connection unit comprising a second connection surface to which a second connection member connects; and
a fourth connection unit extending outwardly from a part of an outer edge of the third connection unit and including a second quantity of contacts larger than the first quantity of contacts, wherein the second quantity of contacts connects the second pad to a second interconnection layer.

12. A semiconductor apparatus comprising:
an integrated circuit;
an interconnection layer electrically connected to the integrated circuit; and
an external connection pad apparatus including a plurality of first pads, each first pad having a first surface area, and a plurality of second pads, each second pad having a second surface area larger than the first surface area, wherein each of the plurality of first pads and each of the plurality of second pads are electrically connected with the interconnection layer.

13. The semiconductor apparatus of claim 12, wherein the first pad comprises a pad through which data is at least one of transmitted and received.

14. The semiconductor apparatus of claim 12, wherein the first pad comprises a first connection unit including a connection surface to which a connection member connects; and
wherein a distance from an outer edge of the first connection unit to an outer edge of the connection surface is formed equally at various perimeter points of the outer edge of the first connection unit.

15. The semiconductor apparatus of claim 14, wherein the first pad includes a second connection unit extending outwardly from a part of the outer edge of the first connection unit, and
wherein the second connection unit includes a first quantity of contacts connecting the first pad to the interconnection layer.

16. The semiconductor apparatus of claim 12, wherein the first pad comprises a polygonal shape having five or more angles.

17. The semiconductor apparatus of claim 12, wherein the first pad has a shape comprising at least one chamfered edge from a rectangular pad area having a predetermined size.

18. The semiconductor apparatus of claim 12, wherein the second pad is a pad configured to receive at least one of a power signal and a control signal.

19. The semiconductor apparatus of claim 12, wherein the second pad includes a first connection unit, the first connection unit comprising a connection surface to which a connection member connects; and
wherein the first connection unit comprises a rectangular shape having a predetermined size.

20. The semiconductor apparatus of claim 19, wherein the second pad includes a second connection unit extending outwardly from a part of an outer edge of the first connection unit, and
wherein the second connection unit connects the second pad to the interconnection layer and includes a second quantity of contacts, wherein the quantity is two or more.

21. The semiconductor apparatus of claim 12, wherein the first pad has a shape comprising at least one chamfered edge from a rectangular pad area having a predetermined size, and
wherein the second pad comprises a rectangular shape having the predetermined size.

22. The semiconductor apparatus of claim 12, further comprising:
a plurality of chip pads electrically connected with the interconnection layer; and
a re-distribution layer (RDL) connecting the plurality of chip pads with the external connection pad apparatus.

23. An external connection pad apparatus comprising:
a plurality of first pads, each first pad having a first surface area, comprising a first connection unit including a first connection surface to which a first connection member connects, and comprising a second connection unit extending outwardly from the first connection unit, wherein the second connection unit includes at least one contact connecting the first pad to a first interconnection layer; and
a plurality of second pads, each second pad having a second surface area larger than the first surface area, comprising a third connection unit including a second connection surface to which a second connection member connects, and comprising a fourth connection unit extending outwardly from the third connection unit, wherein the fourth connection unit includes at least one contact connecting the second pad to a second interconnection layer.

24. The external connection pad apparatus of claim 23, wherein the first pad has a shape comprising at least one chamfered edge from a rectangular pad area having a predetermined size, and wherein the second pad comprises a rectangular shape having the predetermined size.
